(19) United States
(12) Patent Application Publication
(10) Pub. No.: US 2024/0071895 A1
(43) Pub. Date: Feb. 29, 2024

(54) SEMICONDUCTOR PACKAGE

(71) Applicant: SAMSUNG ELECTRONICS CO., LTD., Suwon-Si (KR)

(72) Inventors: Seoeun KYUNG, Suwon-si (KR); Byung Ho KIM, Suwon-si (KR); Youngbae KIM, Suwon-si (KR); Hongwon KIM, Suwon-si (KR); Seokwon LEE, Suwon-si (KR); Jae-Ean LEE, Suwon-si (KR); Dahee KIM, Suwon-si (KR)

(21) Appl. No.: 18/353,279

(22) Filed: Jul. 17, 2023

(30) Foreign Application Priority Data
Aug. 31, 2022 (KR) 10-2022-0109843

(51) Int. Cl. H01L 23/498; H01L 23/00; H01L 23/538; H01L 25/10; H01L 25/18

(52) U.S. Cl. CPC H01L 23/49838; H01L 23/5386; H01L 24/16; H01L 25/105; H01L 25/18; H01L 23/3128; H01L 23/49822; H01L 23/5385; H01L 24/48; H01L 2224/16227; H01L 2224/48091; H01L 2224/48105; H01L 2224/48227; H01L 2225/1035; H01L 2225/1058

(57) ABSTRACT

A semiconductor package may include a lower redistribution layer including a lower wiring and a lower via, an embedded region on the lower redistribution layer, a core layer on the lower redistribution layer and including a core via, and an under bump structure including an under bump pad on a lower surface of the lower redistribution layer and an under bump via connecting the lower wiring and the under bump pad, the under bump pad may overlap the under bump via, the lower via, and the core via in a plan view, and the under bump via may be spaced apart from at least one of the lower via and the core via in the plan view.

### CROSS-REFERENCE TO RELATED APPLICATIONS

This U.S. non-provisional patent application claims priority under 35 U.S.C. § 119 to Korean Patent Application No. 10-2022-0109843, filed on Aug. 31, 2022, in the Korean Intellectual Property Office, the entire contents of which are hereby incorporated by reference.

### TECHNICAL FIELD

The inventive concept relates to a semiconductor package, and more particularly, relates to a semiconductor package including a redistribution substrate, and a method of manufacturing the same.

### DISCUSSION OF RELATED ART

A semiconductor package is typically a casing containing one or more discrete semiconductor devices or integrated circuit chips. For example, the semiconductor package may include a semiconductor chip mounted on a printed circuit board (PCB). Bonding wires or bumps may be used to electrically connect the semiconductor chip to the printed circuit board.

### SUMMARY

Embodiments of the inventive concept provide a semiconductor package having improved reliability and durability.

A semiconductor package according to some embodiments of the inventive concept may include a lower redistribution layer including a lower wiring and a lower via, a core layer on the lower redistribution layer and including a core via, and an under bump structure including an under bump pad on a lower surface of the lower redistribution layer and an under bump via connecting the lower wiring and the under bump pad, the under bump pad may overlap the under bump via, the lower via, and the core via in a plan view, and the under bump via may be spaced apart from at least one of the lower via and the core via in the plan view.

A semiconductor package according to some embodiments of the inventive concept may include a semiconductor chip, a lower redistribution layer including a lower via and a lower wiring on a lower surface of the semiconductor chip, an upper redistribution layer on an upper surface of the semiconductor chip, a connection structure connecting between the lower redistribution layer and the upper redistribution layer and located on a side of the semiconductor chip, an under bump pad on a lower surface of the lower redistribution layer, and an under bump via between the lower wiring and the under bump pad, the lower via, the connection structure, and the under bump via may overlap the under bump pad, in a plan view, and the lower via may be spaced apart from the under bump via, in the plan view.

A semiconductor package according to some embodiments of the inventive concept may include a lower package and an upper package disposed on the lower package and including an upper semiconductor chip, the lower package may include a lower redistribution layer including a lower insulating layer, a seed pattern, a lower via, and a lower wiring, a lower semiconductor chip on the lower redistribution layer, a core layer surrounding the lower semiconductor chip on the lower redistribution layer and including a core insulating pattern, a core via, and a core pad, an under bump structure provided on a lower surface of the lower redistribution layer and including an under bump pad and a plurality of under bump vias, an external terminal connected on a lower surface of the under bump pad, a molding layer covering the lower semiconductor chip and the core layer on the lower redistribution layer, and an upper redistribution layer connected to the lower redistribution layer through the core layer on the molding layer, the lower via, the core via, and the plurality of under bump vias may be disposed on the under bump pad, and the lower via, the core via, and the plurality of under bump vias may not be vertically aligned with each other.

### BRIEF DESCRIPTION OF THE DRAWINGS

Example embodiments will be more clearly understood from the following detailed description taken in conjunction with the accompanying drawings. The accompanying drawings represent non-limiting, example embodiments as described herein.

FIG. 1 is a cross-sectional view illustrating a semiconductor package according to an embodiment of the inventive concept.

FIG. 2A is an enlarged view illustrating region “A” of FIG. 1 according to an embodiment of the inventive concept.

FIG. 2B is plan view illustrating a core via, a first lower via, an under bump via, and an under bump pad of FIG. 2A.

FIG. 3A is an enlarged view illustrating region “A” of FIG. 1 according to an embodiment of the inventive concept.

FIG. 3B is a plan view illustrating a core via, a first lower via, an under bump via, and an under bump pad of FIG. 3A.

FIG. 4A is an enlarged views illustrating region “A” of FIG. 1 according to an embodiment of the inventive concept.

FIG. 4B is a plan view illustrating a core via, a first lower via, an under bump via, and an under bump pad of FIG. 4A.

FIG. 5A is an enlarged views illustrating region “A” of FIG. 1 according to an embodiment of the inventive concept.

FIG. 5B is a plan view illustrating a core via, a first lower via, an under bump via, and an under bump pad of FIG. 5A.

FIG. 6 is a cross-sectional view illustrating a semiconductor package according to an embodiment of the inventive concept.

FIG. 7A is an enlarged view of region “B” of FIG. 6 according to an embodiment of the inventive concept.

FIG. 7B is a plan view illustrating a conductive structure, a lower redistribution pad via, an under bump via, and an under bump pad of FIG. 7A.

FIG. 8 is cross-sectional view illustrating a semiconductor package according to an embodiment of the inventive concept.

FIG. 9 is a cross-sectional view illustrating a semiconductor package according to an embodiment of the inventive concept.

FIG. 10 is a cross-sectional view illustrating a semiconductor package according to embodiments of the inventive concept.

### DETAILED DESCRIPTION

Hereinafter, embodiments of the inventive concept will be described with reference to the accompanying drawings. Like reference numerals may refer to like elements throughout the specification.

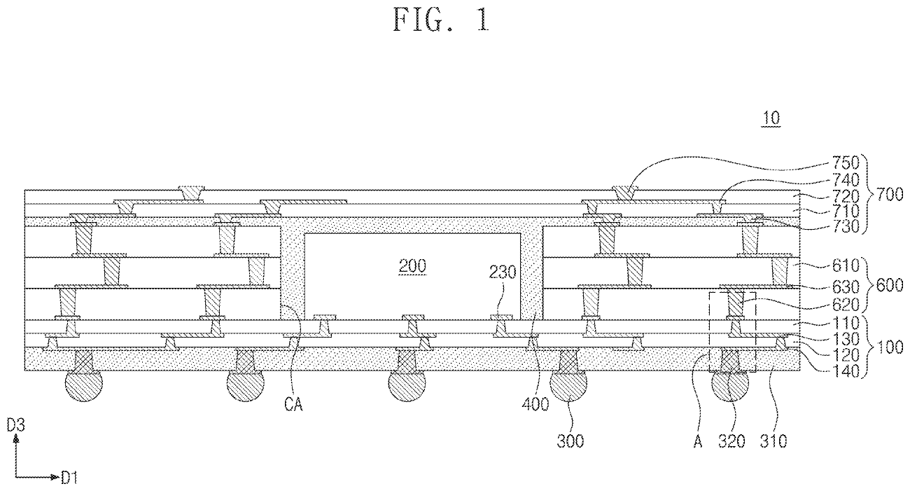

FIG. 1 is a cross-sectional view illustrating a semiconductor package according to an embodiment of the inventive concept.

Referring to FIG. 1, a semiconductor package 10 may include a lower redistribution layer 100, a semiconductor chip 200, a solder ball 300, a molding layer 400, a core layer 600, and an upper redistribution layer 700.

The semiconductor chip 200 may be mounted on an upper surface of the lower redistribution layer 100. The semiconductor chip 200 may be disposed on a center region of the lower redistribution layer 100 in a plan view. The semiconductor chip 200 may be one of a logic chip, a buffer chip, and a memory chip. In an example in which the semiconductor chip 200 is a logic chip, the logic chip may include an ASIC chip and an application processor (AP) chip. The ASIC chip may include an application specific integrated circuit (ASIC). As another example, the semiconductor chip 200 may include a central processing unit (CPU) or a graphics processing unit (GPU). In an example in which the semiconductor chip 200 is a memory chip, the memory chip may include a high bandwidth memory (HBM) chip. According to an embodiment of the inventive concept, the semiconductor chip 200 may include two or more different semiconductor chips.

In an embodiment, the semiconductor chip 200 may have an upper surface and a lower surface opposite to each other. The lower surface of the semiconductor chip 200 may be in direct physical contact with the lower redistribution layer 100. The semiconductor chip 200 may include integrated circuits and chip pads, such as chip pad 230. The integrated circuits may be provided in the semiconductor chip 200. The chip pad 230 may be provided on the lower surface of the semiconductor chip 200 to be connected to the integrated circuits. When a component is electrically connected to the semiconductor chip 200, it may mean electrically connected to the integrated circuits through the chip pads of the semiconductor chip 200. A first direction D1, as illustrated, may be parallel to the upper surface of the semiconductor chip 200. A third direction D3, as illustrated, may be substantially perpendicular to the upper surface of the semiconductor chip 200.

In an embodiment, the core layer 600 may be provided on the lower redistribution layer 100. The core layer 600 may extend in one direction. The core layer 600 may include a core pattern from which a portion is removed in a plan view. That is, the portion of the core layer 600 may be removed to provide an embedded region CA. The embedded region CA may have an open hole shape connecting an upper surface of the core layer 600 and a lower surface of the core layer 600. In an embodiment of the inventive concept, the core layer 600 having the core pattern is exemplarily described, but the inventive concept is not limited thereto. That is, the semiconductor package 10 may include a plurality of core patterns spaced apart from each other in a plan view.

The core layer 600 may include a core insulating pattern 610, and a core via 620 and a core pad 630 that are wiring patterns provided in the core insulating pattern 610.

The core insulating pattern 610 may include an insulating material. For example, the core insulating pattern 610 may include one of glass fiber, a ceramic plate, an epoxy, a resin, and silicon oxide (SiO₂).

The core via 620 and the core pad 630 may be formed of a material including, for example, stainless steel, aluminum (Al), nickel (Ni), magnesium (Mg), zinc (Zn), tantalum (Ta), copper (Cu), or combinations thereof. The core via 620 may be spaced apart from the embedded region CA. For example, the core via 620 may be disposed closer to outside of the core layer 600 than the embedded region CA. The core pad 630 may be provided between two or more core vias. For example, the core pad 630 may be in contact with the core via 620. The core via 620 and the core pad 630 may be electrically connected to the upper redistribution layer 700 and the lower redistribution layer 100.

In an embodiment, a width of the core via 620 may become narrower from an upper surface of the core via 620 to a lower surface of the core via 620. That is, the width of the core via 620 may be relatively wide at the upper surface. In some embodiments, the width of the core via 620 may be constant from the upper surface to the lower surface. A height of one core via 620 may be about 50 μm to 80 μm. Accordingly, a height of the core via 620 of the core layer 600 may be about 100 μm or more. A diameter of the core via 620 may be about 40 μm to 50 μm.

In an embodiment and as illustrated in FIG. 1, the core via 620 and the core pad 630 that are buried in a plurality of stacked core insulating patterns, including core insulating pattern 610, but the inventive concept is not limited thereto. That is, the core insulating pattern 610 of the core layer may be provided as one layer, and the core via 620 may penetrate from an upper surface to a lower surface of the core insulating pattern 610. In this case, the core pad 630 may be provided only on the upper surface and the lower surface of the core insulating pattern 610.

In an embodiment, the semiconductor chip 200 may be provided in the embedded region CA of the core layer 600. The embedded region CA may be a portion of the core layer 600 from which the core pattern is removed. That is, the embedded region CA may have a through hole shape extending from the upper surface of the core layer 600 toward the lower surface of the core layer 600. Embodiments of the inventive concept are not limited thereto.

In an embodiment, the molding layer 400 may be provided on the upper surface of the lower redistribution layer 100 and may cover the semiconductor chip 200 and the core layer 600. For example, the molding layer 400 may cover an upper surface and side surfaces of the semiconductor chip 200. The molding layer 400 may cover an upper surface and side surfaces of the core layer 600. In an embodiment, the molding layer 400 may cover side surfaces of the semiconductor chip 200 and the core layer 600 and expose the upper surfaces thereof. A side surface of the molding layer 400 may be vertically aligned with a side surface of the lower redistribution layer 100. The molding layer 400 may include an insulating polymer such as an epoxy-based molding compound.

In an embodiment, the lower redistribution layer 100 may include a first lower insulating layer 110, a second lower insulating layer 120, a first lower redistribution pattern 130 and a second lower redistribution pattern 140. The first lower insulating layer 110 may be disposed on the lower surface of the semiconductor chip 200 and the lower surface of the core layer 600 to cover the lower surface of the semiconductor chip 200 and the lower surface of the core layer 600. For example, the first lower insulating layer 110 may be in direct contact with the lower surface of the semiconductor chip 200 and the lower surface of the core layer 600. The second lower insulating layer 120 may be disposed on the lower surface of the first lower insulating layer 110 to cover the lower surface of the first lower insulating layer 110 and the first lower redistribution pattern 130. The first lower insulating layer 110 and the second lower insulating layer 120 may each include, for example, an organic material such as a photo-imagable dielectric (PID) material. The photo-imagable dielectric material may include, for example, at least one of a photosensitive polyimide, polybenzoxazole, a phenol-based polymer, and a benzocyclobutene-based polymer. For example, the first lower insulating layer 110 and the second lower insulating layer 120 may include the same material. In this case, an interface between the first lower insulating layer 110 and the second lower insulating layer 120 may not be distinguished in a cross-sectional view. In an embodiment, lower insulating layers (not shown) may be additionally disposed on the lower surface of the second lower insulating layer 120.

In an embodiment, the first lower redistribution patterns, including the first lower redistribution pattern 130, may be provided on the lower surface of the first lower insulating layer 110 and may penetrate the first lower insulating layer 110. The first lower redistribution patterns, including the first lower redistribution pattern 130, may be laterally spaced apart from each other and may be electrically separated from each other. The second lower redistribution patterns, including the second lower redistribution pattern 140, are provided on the lower surface of the second lower insulating layer 120 and may penetrate a portion of the second lower insulating layer 120. The second lower redistribution patterns may penetrate a portion of the second lower insulating layer 120 to be connected to the first lower redistribution patterns 130. The second lower redistribution patterns may be laterally spaced apart from each other and may be electrically separated from each other. The fact that two components are laterally spaced apart from each other may mean that the two components are horizontally spaced apart formed each other. “Horizontal” may be parallel to the upper surface of the semiconductor chip 200 or the first direction D1. The first lower redistribution pattern 130 and the second lower redistribution pattern 140 may include a metal such as copper.

An electrical connection between the lower redistribution layer 100 and other components may electrically connect at least one of the first and second lower redistribution patterns. The first lower redistribution patterns may pass through the first lower insulating layer 110 to be connected to the core pad 630 of the core layer 600 and the chip pads 230 of the semiconductor chip 200. Accordingly, the lower redistribution layer 100 may be electrically connected to the core layer 600 and the semiconductor chip 200.

In an embodiment, a passivation layer 310 may be provided on a lower surface of the second lower insulating layer 120 to cover the second lower insulating layer 120 and the second lower redistribution patterns, including the second lower redistribution pattern 140. The passivation layer 310 may be a protection layer. The passivation layer 310 may have a relatively large elongation. For example, the passivation layer 310 may have the same or greater elongation than that of the first lower insulating layer 110 and the second lower insulating layer 120. Accordingly, the passivation layer 310 may absorb stress. The stress may be caused by a difference in coefficients of thermal expansion of components, but is not limited thereto. The passivation layer 310 may include, for example, silicone, a polymer, an adhesive insulating film, or a photo-imagable dielectric (PID) material. The polymer may be, for example, a polyimide or an epoxy-based polymer. The adhesive insulating film may include Ajinomoto Build Up Film (ABF).

In an embodiment, an under bump structure 320 may be disposed on the lower surface of the passivation layer 310 and may penetrate a portion of the passivation layer 310. The under bump structure 320 may penetrate a portion of the passivation layer 310 to be connected to the second lower redistribution patterns. The under bump structure 320 may include a metal such as copper.

In an embodiment, the solder ball 300 may be disposed on the lower surface of the passivation layer 310. For example, the solder ball 300 may be disposed on the corresponding under bump structure 320 to be connected to the under bump structure 320. In an embodiment, the solder ball 300 may be an external terminal. The solder ball 300 may include a solder material. The solder material may include, for example, tin, bismuth, lead, silver, or alloys thereof.

In an embodiment, the upper redistribution layer 700 may be provided on the upper surface of the molding layer 400. The upper redistribution layer 700 may include a first upper insulating layer 710, a second upper insulating layer 720, a first upper redistribution pattern 730, a second upper redistribution pattern 740, and redistribution pads 750.

The first upper insulating layer 710 and the second upper insulating layer 720 may be sequentially stacked on the molding layer 400. The first upper insulating layer 710 and the second upper insulating layer 720 may be organic insulating layers. The first upper insulating layer 710 and the second upper insulating layer 720 may include an adhesive insulating film such as an Ajinomoto build-up film. According to other examples, the first upper insulating layer 710 and the second upper insulating layer 720 may include a photo-imagable dielectric material. In one example, the first upper insulating layer 710 and the second upper insulating layer 720 may include the same material. In this case, an interface between the first upper insulating layer 710 and the second upper insulating layer 720 may not be distinguished in a cross-sectional view. In an embodiment, upper insulating layers (not shown) may be additionally disposed on the upper surface of the second upper insulating layer 720.

In an embodiment, the first upper redistribution patterns 730 are provided on the upper surface of the molding layer 400 and may penetrate a portion of the molding layer 400. The first upper redistribution patterns 730 may be laterally spaced apart from each other and may be electrically separated from each other.

In an embodiment, the second upper redistribution pattern 740 may be provided on the upper surface of the first upper insulating layer 710 and may penetrate a portion of the first upper insulating layer 710. The second upper redistribution pattern 740 may penetrate a portion of the first upper insulating layer 710 to be connected to the first upper redistribution pattern 730. The second upper redistribution patterns, including the second upper redistribution pattern 740, may be laterally spaced apart from each other and may be electrically separated from each other. The first upper redistribution pattern 730 and the second upper redistribution pattern 740 may include a metal such as copper.

In an embodiment, an electrical connection between the upper redistribution layer 700 and other components may include being electrically connected to at least one of the first upper redistribution pattern 730 and the second upper redistribution pattern 740. The first upper redistribution pattern 730 may pass through a portion of the molding layer 400 to be connected to the core pad 630 of the core layer 600. Accordingly, the upper redistribution layer 700 may be electrically connected to the core layer 600, and the upper redistribution layer 700 may be electrically connected to the lower redistribution layer 100 through the core layer 600.

In an embodiment, the redistribution pad 750 may be disposed on the second upper insulating layer 720 to penetrate a portion of the second upper insulating layer 720. The redistribution pads, including the redistribution pad 750, may be laterally spaced apart from each other. The redistribution pad 750 may pass through the second upper insulating layer 720 to be connected to the second upper redistribution pattern 740. Accordingly, the redistribution pad 750 may be electrically connected to the core layer 600 and the lower redistribution layer 100 through the second upper redistribution patterns 740. The redistribution pad 750 may include, for example, a metal such as copper.

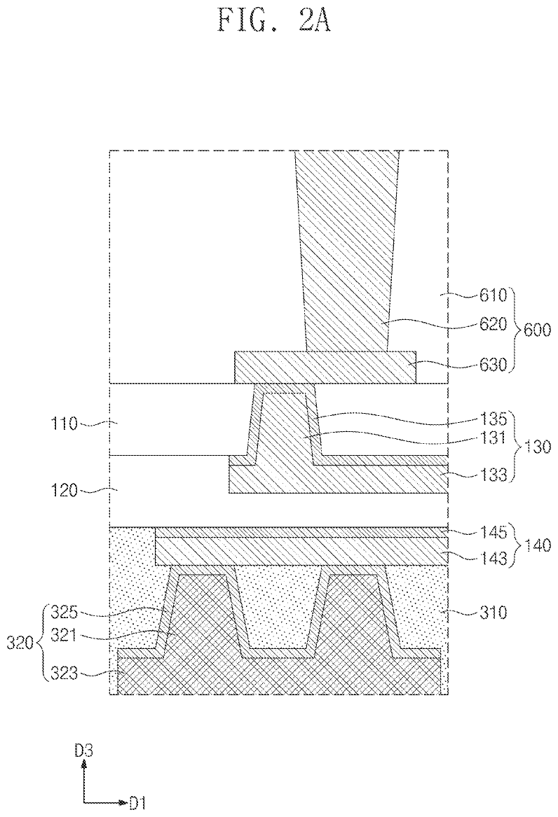

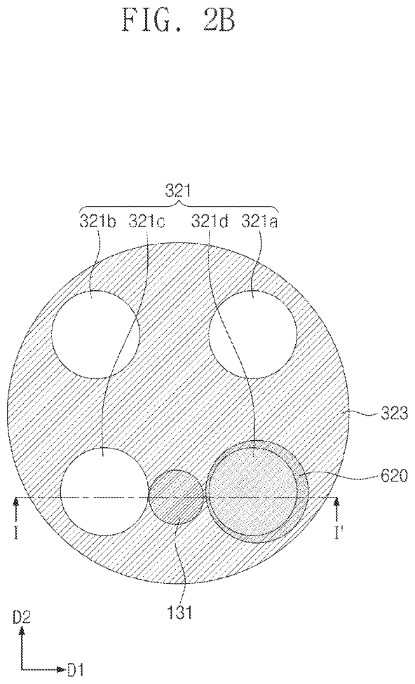

FIGS. 2A, 3A, 4A, and 5A are enlarged views illustrating region “A” of FIG. 1 according to example embodiments. FIGS. 2B, 3B, 4B, and 5B are plan views illustrating a core via, a first lower via, an under bump via, and an under bump pad of FIGS. 2A, 3A, 4A, and 5A, respectively. That is, FIGS. 2A, 3A, 4A, and 5A correspond to cross-sectional views taken along line II′ of FIGS. 2B, 3B, 4B, and 5B, respectively.

Hereinafter, for convenience of description, descriptions of the same items as those described with reference to FIG. 1 may be omitted and differences will be described in detail.

Referring to FIGS. 2A, 3A, 4A and 5A, the first lower insulating layer 110 may be disposed on the lower surface of the core layer 600 and may cover the core insulating pattern 610 and the core pad 630 of the core layer 600. The first lower redistribution pattern 130 may be provided on the lower surface of the first lower insulating layer 110.

The first lower redistribution pattern 130 may include a first lower via 131, a first lower wiring 133, and a first seed pattern 135. As the first lower via 131 of the first lower redistribution pattern 130 passes through the first lower insulating layer 110, and the first lower via 131 may be provided in the first lower insulating layer 110. The first lower via 131 of the first lower redistribution pattern 130 may be connected to the core pad 630 disposed on the lower surface of the core via 620. A width of the first lower via 131 of the first lower redistribution pattern 130 may increase from an upper surface to a lower surface. That is, the width of the first lower via 131 of the first lower redistribution pattern 130 may relatively narrow at the upper surface. In an embodiment, the width of the first lower via 131 of the first lower redistribution pattern 130 may be constant from the upper surface to the lower surface. A height of the first lower via 131 of the first lower redistribution pattern 130 in the third direction D3 may be about 5 μm to 10 μm. A diameter of the first lower via 131 may be about 15 μm to about 25 μm.

In the present specification, a via may be configured for vertical connection, and a wiring may be configured for horizontal connection. “Vertical” may mean being parallel to the third direction D3. In this specification, a level may mean a vertical level, and a level difference may be measured in the third direction D3.

A first lower wiring 133 of the first lower redistribution pattern 130 may be provided on the lower surface of the first lower via 131 and may be connected to the first lower via 131 without an interface. That is, a material forming the lower surface of the first lower via 131 and the first lower via 131 may be formed as a unitary material by a single process step. In an embodiment, the first lower via 131 and the first lower wiring 133 may be formed by a dual damascene process. A width of the first lower wiring 133 may be greater than a width of a lower surface of the first lower via 131. The first lower wiring 133 may extend onto a lower surface of the first lower insulating layer 110.

The first seed pattern 135 of the first lower redistribution pattern 130 may be provided on the first lower via 131 and the first lower wiring 133 of the first lower redistribution pattern 130. In detail, the first seed pattern 135 may cover the upper surface and side surfaces of the first lower via 131 and the upper surface of the first lower wiring 133 of the first lower redistribution pattern 130. The first seed pattern 135 may not extend onto the side surface of the first lower wiring 133. The first seed pattern 135 may be positioned between the first lower via 131 and the core pad 630 of the core layer 600. That is, the first seed pattern 135 may be in direct contact with the core pad 630. The first seed pattern 135 may include a material different from a material of the first lower via 131 and the first lower wiring 133. For example, the first seed pattern 135 may include a conductive seed material. The conductive seed material may include copper, titanium, and/or alloys thereof. The first seed pattern 135 may function as a barrier layer to prevent diffusion of a material included in the first lower via 131 and the first lower wiring 133.

The second lower insulating layer 120 may be disposed on the lower surface of the first lower insulating layer 110 to cover the first lower insulating layer 110 and the first lower redistribution pattern 130. The second lower redistribution pattern 140 may be provided on a lower surface of the second lower insulating layer 120.

The second lower redistribution pattern 140 may include a second lower wiring 143 and a second seed pattern 145. The second lower wiring 143 may extend onto the lower surface of the second lower insulating layer 120. The second seed pattern 145 may be provided on the upper surface of the second lower wiring 143. The second seed pattern 145 may be substantially the same as the first seed pattern 135.

Although not shown in the drawings, the second lower redistribution pattern 140 may further include a second lower via (not shown). The second lower via may pass through a portion of the second lower insulating layer 120 to be provided in the second lower insulating layer 120.

The passivation layer 310 may be disposed on the lower surface of the second lower insulating layer 120 to cover the second lower insulating layer 120 and the second lower redistribution pattern 140. The under bump structure 320 may be provided on the lower surface of the passivation layer 310.

The under bump structure 320 may include an under bump via 321, an under bump pad 323, and an under bump seed pattern 325. As the under bump via 321 of the under bump structure 320 penetrates a portion of the passivation layer 310, and the under bump via 321 may be provided in the passivation layer 310. A plurality of under bumps, including the under bump via 321, may be provided in each under bump structure 320. The under bump via 321 of the under bump structure 320 may be connected to the second lower wiring 143 of the second lower redistribution pattern 140. A width of the under bump via 321 of the under bump structure 320 may increase from an upper surface of the under bump via 321 to a lower surface of the under bump via 321. That is, the width of the under bump via 321 of the under bump structure 320 may be relatively narrow at the upper surface. In an embodiment, the width of the under bump via 321 of the under bump structure 320 may be constant from the upper surface to the lower surface. A height of the under bump via 321 in the third direction D3 may be about 10 μm to 20 μm. A diameter of the under bump via 321 may be about 40 μm to 50 μm.

The under bump pad 323 of the under bump structure 320 may be provided on the lower surface of the under bump via 321 and may be connected to the under bump via 321 without an interface. That is, a material forming the under bump pad 323 and the under bump via 321 may be formed as a unitary material by a single process step. In an embodiment, the under bump via 321 and the under bump pad 323 may be formed by a dual damascene process. The width of the under bump pad 323 may be greater than the width of the lower surface of the under bump via 321.

The under bump seed pattern 325 may be provided on the under bump via 321 and the under bump pad 323. In detail, the under bump seed pattern 325 may cover the upper surface and side surfaces of the under bump via 321 and the upper surface of the under bump pad 323. The under bump seed pattern 325 may be interposed between the under bump via 321 and the second lower wiring 143 of the second lower redistribution pattern 140. The under bump seed pattern 325 may include a conductive seed material. The under bump seed pattern 325 may include a material different from a material of the under bump via 321 and the under bump pad 323. For example, the under bump seed pattern 325 may include titanium or a titanium-copper alloy. As another example, the under bump seed pattern 325 may include the same material as the under bump via 321 and the under bump pad 323. In this case, an interface between the under bump seed pattern 325 and the under bump via 321 and the under bump pad 323 may not be distinguished in a cross-sectional view.

Referring to FIGS. 2A and 2B, the under bump via 321 of the under bump structure 320 may include first under bump via 321a, second under bump via 321b, third under bump via 321c, and fourth under bump via 321d. The first to fourth under bump vias 321a, 321b, 321c, and 321d may be disposed on the upper surface of the under bump pad 323 at regular intervals. That is, the first to fourth under bump vias 321a, 321b, 321c, and 321d may not overlap each other in a plan view.

In a plan view, the first to fourth under bump vias 321a, 321b, 321c and 321d of the under bump structure 320, the core via 620 of the core layer 600, and the first lower via 131 of the first lower redistribution pattern 130 may overlap the under bump pad 323 of the under bump structure 320. That is, the first to fourth under bump vias 321a, 321b, 321c, and 321d, the first lower via 131, and the core via 620 may be disposed on the under bump pad 323.

A diameter of each of the first to fourth under bump vias 321a, 321b, 321c, and 321d, a diameter of the core via 620, and a diameter of the first lower via 131 may be smaller than a diameter of the under bump pad 323. A diameter of each of the first to fourth under bump vias 321a, 321b, 321c, and 321d may be substantially the same as each other. The diameter of the core via 620 may be greater than, or substantially equal to, the diameter of each of the first to fourth under bump vias 321a, 321b, 321c, and 321d. The diameter of the first lower via 131 may be smaller than the diameter of each of the first to fourth under bump vias 321a, 321b, 321c, and 321d and the diameter of the core via 620.

In a plan view, the core via 620 of the core layer 600 may completely overlap one of the first to fourth under bump vias 321a, 321b, 321c, and 321d. In an embodiment, a portion of the core via 620 may overlap at least one of the first to fourth under bump vias 321a, 321b, 321c, and 321d. The first lower via 131 of the first lower redistribution pattern 130 may not overlap the core via 620 and the first to fourth under bump vias 321a, 321b, 321c, and 321d. In other words, the first lower via 131 may not be vertically aligned with the core via 620 and the first to fourth under bump vias 321a, 321b, 321c, and 321d.

The first lower via 131 may be formed to be spaced apart from the core via 620 in the first direction D1. In detail, the core pad 630 of the core layer 600 extending in the first direction D1 may be formed. A diameter of the core pad 630 may be greater than the sum of the diameter of the core via 620 and the diameter of the first lower via 131. In an embodiment, after the first lower insulating layer 110 is patterned using a mask, the first lower via 131 spaced apart from the core via 620 in the first direction D1 may be formed.

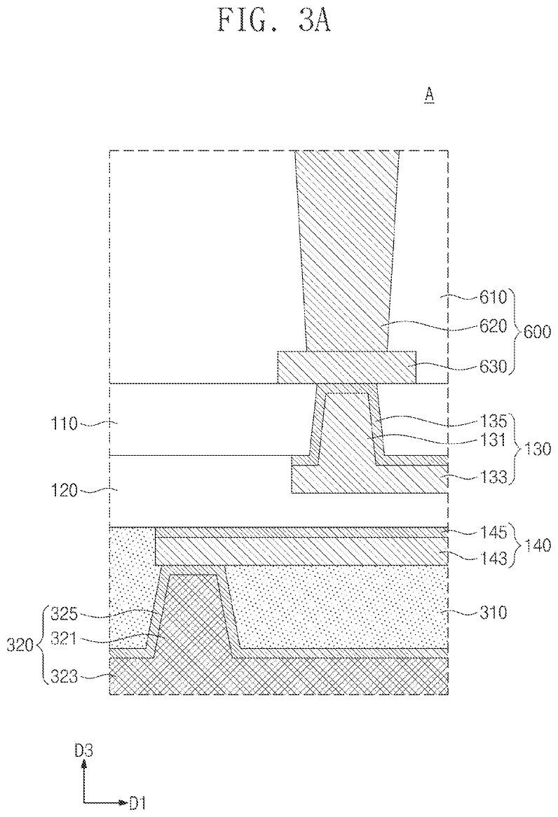

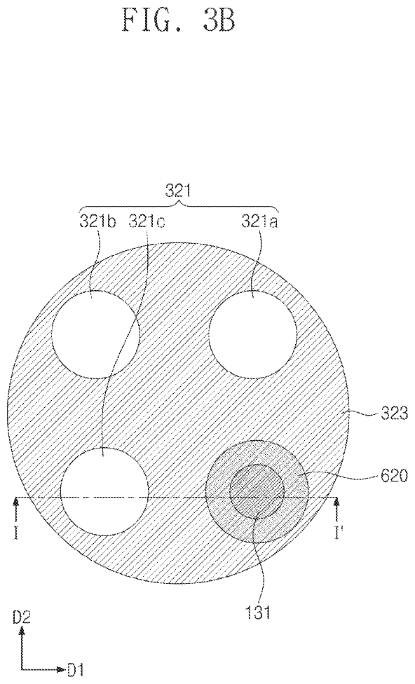

Referring to FIGS. 3A and 3B, the under bump via 321 of the under bump structure 320 may include first to third under bump vias 321a, 321b, and 321c. In detail, in a form in which the first to fourth under bump vias 321a, 321b, 321c, and 321d are arranged at regular intervals as shown in FIG. 2B, the fourth under bump via 321d may be omitted.

In a plan view, the core via 620 of the core layer 600 and the first lower via 131 of the first lower redistribution pattern 130 may overlap each other. The core via 620 and the first lower via 131 may be disposed at a position of the omitted under bump via. That is, the overlapping first lower via 131 and the core via 620 may be horizontally spaced apart from the first to third under bump vias 321a, 321b, and 321c at regular intervals.

The fourth under bump via 321d may be omitted from the under bump structure 320 of FIG. 2B. In detail, the passivation layer 310 may be patterned using a mask of the under bump structure 320 in which the under bump via positioned below the core via 620 and the first lower via 131 is omitted. In an embodiment, only the first to third under bump vias 321a, 321b, and 321c may be formed. Accordingly, at least one of the first to third under bump vias 321a, 321b, and 321c may be prevented from being vertically aligned with the first lower via 131 and the core via 620.

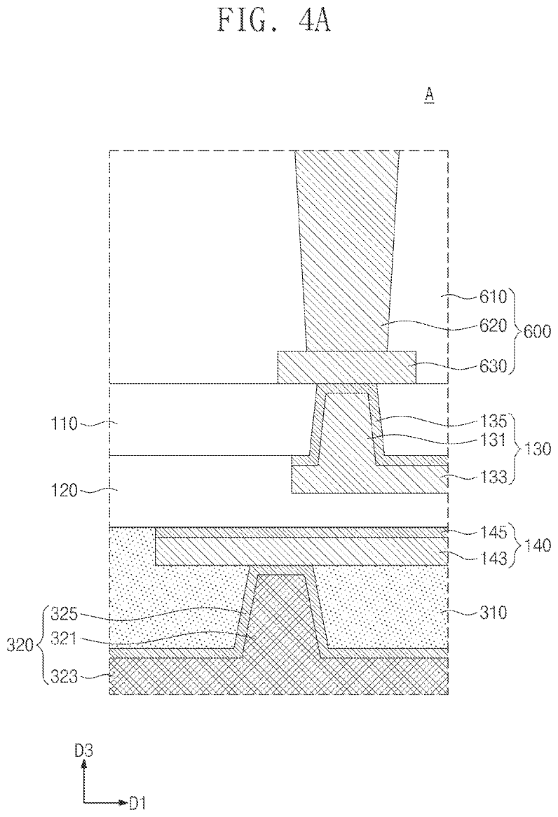

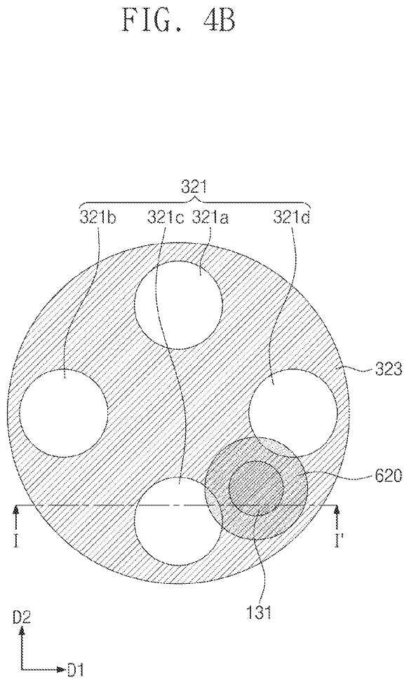

Referring to FIGS. 4A and 4B, the under bump via 321 of the under bump structure 320 may include first to fourth under bump vias 321a, 321b, 321c, and 321d.

In a plan view, the core via 620 of the core layer 600 and the first lower via 131 of the first lower redistribution pattern 130 may overlap each other, and may be disposed between the first to fourth under bump vias 321a, 321b, 321c, and 321d. That is, the first lower via 131 may not overlap the first to fourth under bump vias 321a, 321b, 321c, and 321d. A portion of the core via 620 may partially overlap at least one of the first to fourth under bump vias 321a, 321b, 321c, and 321d. In an embodiment, the core via 620 may not overlap the first to fourth under bump vias 321a, 321b, 321c, and 321d.

According to an embodiment of the inventive concept, a structure as illustrated in FIG. 4B may be formed by rotating the under bump structure 320 of FIG. 2B. In detail, the passivation layer 310 may be patterned using a mask of the under bump structure 320 rotated in a clockwise or counterclockwise direction on a plane formed in the first and second directions D1 and D2, as illustrated. Accordingly, vertically aligning the first to fourth under bump vias 321a, 321b, 321c, and 321d with the first lower via 131 and the core via 620 may be avoided. The rotated angle may be 40°, 60° or 90°, for example, but is not limited thereto.

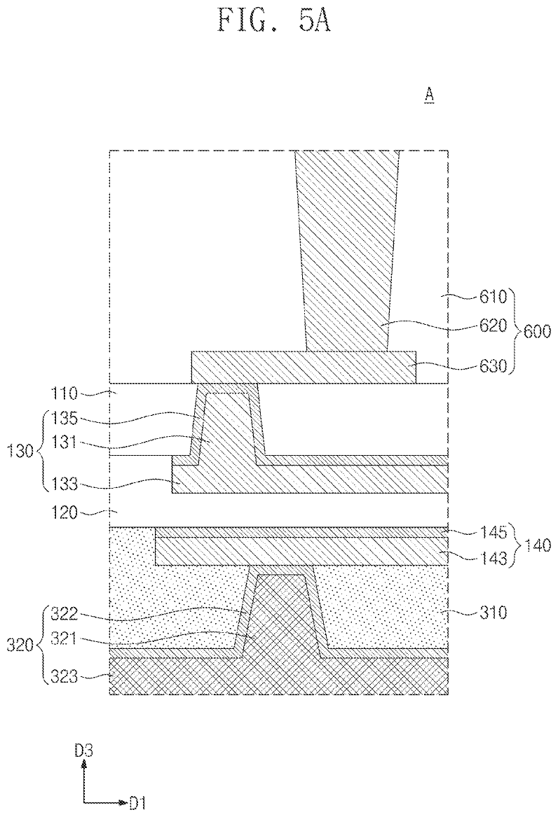

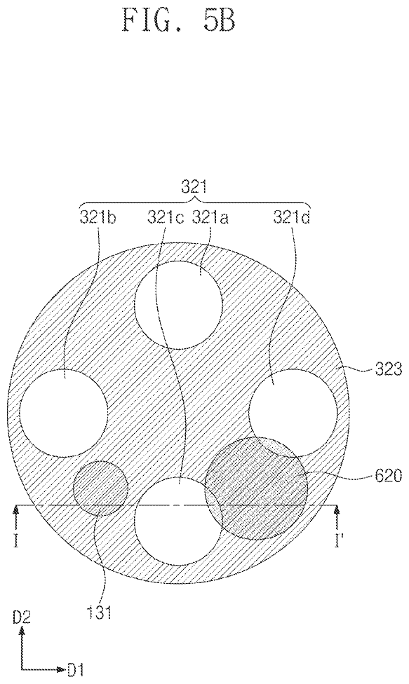

Referring to FIGS. 5A and 5B, the under bump via 321 of the under bump structure 320 may include first to fourth under bump vias 321a, 321b, 321c, and 321d.

In a plan view, the first lower via 131 of the first lower redistribution pattern 130 may be spaced apart from the core via 620 of the core layer 600. The first lower via 131 may be disposed between the first to fourth under bump vias 321a, 321b, 321c, and 321d to be spaced apart from each other. That is, the first lower via 131 may not overlap the core via 620 and the first to fourth under bump vias 321a, 321b, 321c, and 321d.

In a plan view, the core via 620 may be positioned between the first to fourth under bump vias 321a, 321b, 321c, and 321d without overlapping the first lower via 131. A portion of the core via 620 may overlap at least one of the first to fourth under bump vias 321a, 321b, 321c, and 321d. In an embodiment, the core via 620 may not overlap the first to fourth under bump vias 321a, 321b, 321c, and 321d.

According to an embodiment of the inventive concept and referring to FIG. 5B, the first lower insulating layer 110 may be patterned using a mask having a shape of a first lower via 131 located under the core pad 630 and spaced apart from the core via 620 in the first direction D1. In an embodiment, after the first lower redistribution pattern 130 including the first lower via 131 spaced apart from the core via 620 in the first direction D1 is formed, the passivation layer 310 may be patterned using a mask of the under bump structure 320 rotated clockwise or counterclockwise, thereby forming the under bump structure. Accordingly, vertically aligning the core via 620, the first lower via 131 with the first to fourth under bump vias 321a, 321b, 321c, and 321d may be avoided.

Referring back to FIGS. 2B, 3B, 4B and 5B, the under bump via 321 of the under bump structure 320 may include first to third under bump vias 321a, 321b, 321c or first to the fourth under bump vias 321a, 321b, 321c, and 321d, and thus cracks due to stress may be prevented.

A sum of heights of the core via 620, the first lower via 131, and the under bump via 321 may be about 100 μm or more. Accordingly, when the core via 620, the first lower via 131, and the under bump via 321 are vertically aligned, a significant compressive stress may be applied to the first lower via 131 due to a weight of the upper package, which will be described later. Accordingly, cracks may occur between the core pad 630 and the first lower via 131.

According to an embodiment of the inventive concept, a structure avoids vertically aligning the core via 620, the first lower via 131, and one of the first to fourth under bump vias 321a, 321b, 321c, and 321d. Accordingly, external force due to the weight of the upper package may be dispersed and thus the compressive stress applied to the first lower via 131 may be reduced. Accordingly, the cracks between the core pad 630 and the first lower via 131 may be prevented, thereby improving reliability of the semiconductor package.

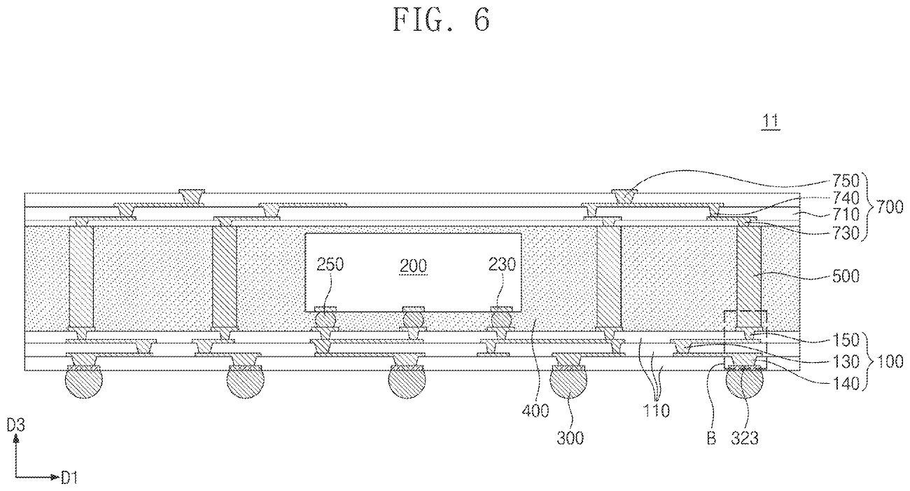

FIG. 6 is a cross-sectional view illustrating a semiconductor package according to an embodiment of the inventive concept.

Referring to FIG. 6, a semiconductor package 11 may include a lower redistribution layer 100, a semiconductor chip 200, solder balls, including solder ball 300, a molding layer 400, conductive structures, such as conductive structure 500, and an upper redistribution layer 700. In an embodiment, the semiconductor package 11 may be a low profile package.

The lower redistribution layer 100 may include a lower insulating layer 110, under bump pads, including under bump pad 323, a first lower redistribution pattern 130, a second lower redistribution pattern 140, and lower redistribution pads, including lower redistribution pad 150. The lower insulating layer 110 may include, for example, an organic material such as a photo-imagable dielectric (PID) material. The photo-imagable dielectric material may be a polymer. The photo-imagable dielectric material may include, for example, at least one of a photosensitive polyimide, polybenzoxazole, a phenol-based polymer, and a benzocyclobutene-based polymer. The lower insulating layer 110 may be provided in plurality. That is, the number of stacked lower insulating layers 110 may be varied for different implementations. In an embodiment, the plurality of lower insulating layers 110 may include the same material. In this case, an interface between the adjacent lower insulating layers 110 may not be distinguished in a cross-sectional view.

In an embodiment, the under bump pads, including the under bump pad 323, may be provided in the lowermost of the lower insulating layer 110. Lower surfaces of the under bump pads may not be covered by the lowermost of the lower insulating layer 110. The under bump pads may function as pads of the solder balls 300. The under bump pads, including the under bump pad 323, may be laterally spaced apart from each other and may be electrically insulated from each other. A lower surface of the lower redistribution layer 100 may include a lower surface of the lowermost of the lower insulating layer 110 and lower surfaces of the under bump pads. The under bump pads may include a metal material such as copper.

The first lower redistribution pattern 130 and the second lower redistribution pattern 140 may be provided on an upper surface of the lower insulating layer 110. The second lower redistribution patterns, including the second lower redistribution pattern 140, may be disposed on the corresponding under bump pad 323. The first lower redistribution patterns, including the first lower redistribution pattern 130, may be disposed on the corresponding second lower redistribution patterns and may be connected to the second lower redistribution patterns. The number of the first and second lower redistribution patterns stacked between the under bump pads and the lower redistribution pads, including the lower redistribution pad 150, may be varied for different implementations.

The lower redistribution pads, including the lower redistribution pad 150, may be disposed on the first lower redistribution patterns, including the first lower redistribution pattern 130, to connect to the first lower redistribution patterns. The lower redistribution pads, including the lower redistribution pad 150, may be laterally spaced apart from each other. Each of the lower redistribution pads, including the lower redistribution pad 150, may be connected to a corresponding under bump pad through the first and second lower redistribution patterns.

The solder ball 300 may be disposed on the lower surface of the lower redistribution layer 100. For example, each of the solder balls, including solder ball 300, may be respectively disposed on the lower surface of the corresponding under bump pad 323 to be connected to the under bump pad 323. The solder balls may be substantially the same as those described with reference to FIG. 1.

The semiconductor chip 200 may be mounted on the upper surface of the lower redistribution layer 100. The semiconductor chip 200 may be disposed on a center region of the lower redistribution layer 100 in a plan view. The semiconductor chip 200 may be substantially the same as that described with reference to FIG. 1.

The semiconductor package 11 may further include bumps, including bump 250. The bumps, including bump 250, may be interposed between the lower redistribution layer 100 and the semiconductor chip 200. For example, each of the bumps may be provided between a corresponding lower redistribution pad, such as the lower redistribution pad 150, and a chip pad 230 to be connected to the lower redistribution pad 150 and the chip pad 230. Accordingly, the semiconductor chip 200 may be connected to the lower redistribution layer 100 through the bumps, including bump 250. The bumps may include a solder material.

The conductive structures, including conductive structure 500, may be disposed on the upper surface of the lower redistribution layer 100. In a plan view, the conductive structures may be disposed on an edge region of the lower redistribution layer 100. The edge region of the lower redistribution layer 100 may surround the center region. That is, the conductive structures may surround the semiconductor chip 200 in a plan view.

The conductive structures, including conductive structure 500, may be horizontally spaced apart from the semiconductor chip 200. The conductive structures may be spaced apart from each other. The conductive structures may be disposed on each of the lower redistribution pads to connect to the lower redistribution pads. Accordingly, the conductive structures, including conductive structure 500, may be electrically connected to the solder balls, including solder ball 300, and/or the semiconductor chip 200 through the lower redistribution layer 100.

The molding layer 400 may be provided on the upper surface of the lower redistribution layer 100 to cover an upper surface and side surfaces of the semiconductor chip 200 and side surfaces of the conductive structures. An upper surface of the molding layer 400 may be coplanar with upper surfaces of the conductive structures. The molding layer 400 may include an insulating polymer such as an epoxy-based molding compound.

The upper redistribution layer 700 may be disposed on the molding layer 400 and the conductive structures, including conductive structure 500, and may be electrically connected to the conductive structures. The upper redistribution layer 700 may include an upper insulating layer 710, first upper redistribution pattern 730, the second upper redistribution pattern 740, and redistribution pads, including redistribution pad 750. Like the lower insulating layer 110, the upper insulating layer 710 may be provided in plurality.

The first upper redistribution pattern 730 and the second upper redistribution pattern 740 may be provided on the upper surface of the molding layer 400. The first upper redistribution pattern 730 may be disposed on the conductive structure 500. The second upper redistribution pattern 740 may be disposed on the first upper redistribution pattern 730 and may be connected to the first upper redistribution pattern 730. The number of the first and second upper redistribution patterns is not limited and may be varied according to an implementation.

Each of the redistribution pads, such as redistribution pad 750, may be disposed on a corresponding second upper redistribution pattern, such as the second upper redistribution pattern 740, to be respectively connected to the second upper redistribution pattern. The redistribution pads, including the redistribution pad 750, may be laterally spaced apart from each other. The first upper redistribution pattern 730 and the second upper redistribution pattern 740 may be provided, and thus at least one redistribution pad may not be vertically aligned with the conductive structure 500 electrically connected thereto. Accordingly, an arrangement of the redistribution pads may be designed freely. The redistribution pad 750 may include, for example, a metal such as copper.

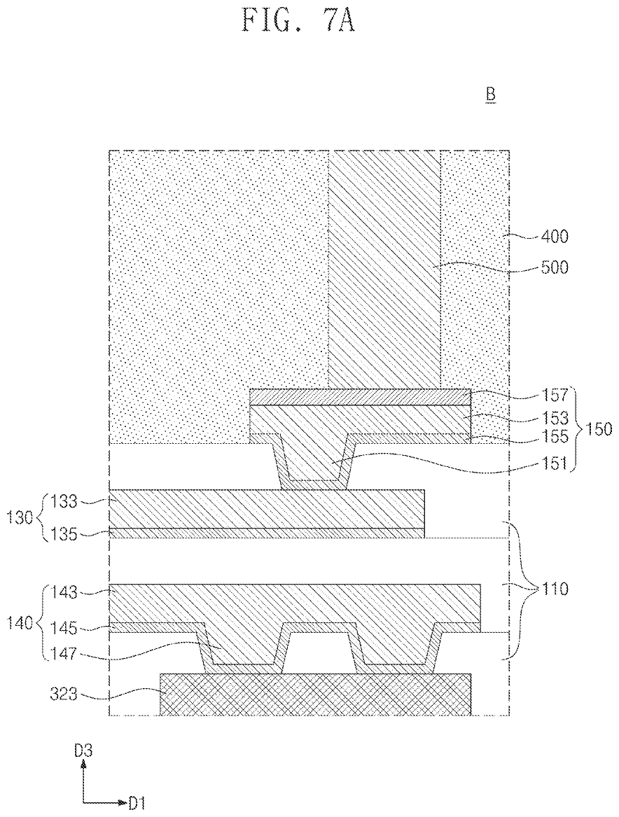

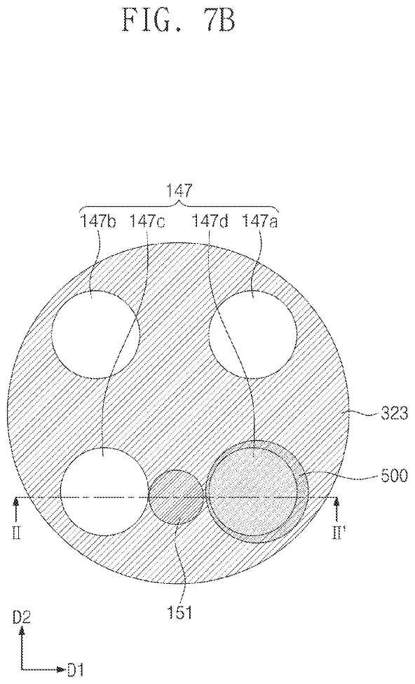

FIG. 7A is an enlarged view of region “B” of FIG. 6. FIG. 7B is a plan view illustrating a conductive structure, a lower redistribution pad via, an under bump via, and an under bump pad. FIG. 7A corresponds to a cross-sectional view taken along line II-II′ of FIG. 7B.

Hereinafter, for convenience of explanation, descriptions of the same items as those described with reference to FIG. 6 may be omitted and differences will be described in detail.

In an embodiment and referring to FIG. 7A, the lower redistribution pad 150 may include a lower redistribution pad via 151, a lower redistribution pad wiring 153, a pad seed pattern 155, and a bonding pad 157. The lower redistribution pad via 151 and the lower redistribution pad wiring 153 may be provided on the pad seed pattern 155. That is, the pad seed pattern 155 may cover the lower surface and side surfaces of the lower redistribution pad via 151 and the lower surface of the lower redistribution pad wiring 153.

The lower redistribution pad via 151 may pass through a portion of the uppermost of the lower insulating layer 110 to be provided in the uppermost of the lower insulating layer 110. The lower redistribution pad via 151 may be connected to the first lower redistribution pattern 130. The width of the lower redistribution pad via 151 may decrease from the upper surface to the lower surface. That is, the width of the lower redistribution pad via 151 may be relatively wide at the upper surface. In an embodiment, the width of the lower redistribution pad via 151 may be constant from the upper surface to the lower surface.

The lower redistribution pad wiring 153 may be provided on the upper surface of the lower redistribution pad via 151. The lower redistribution pad wiring 153 may be connected to the lower redistribution pad via 151 without an interface. That is, a material forming the lower redistribution pad wiring 153 and the lower redistribution pad via 151 may be formed as a unitary material by a single process step. The lower redistribution pad wiring 153 may extend on the top surface of the uppermost of the lower insulating layer 110. A width of the lower redistribution pad wiring 153 may be greater than a width of the lower redistribution pad via 151.

The bonding pad 157 may be provided on the lower redistribution pad wiring 153 to cover an upper surface of the lower redistribution pad wiring 153. That is, the bonding pad 157 may be positioned between the conductive structure 500 and the lower redistribution pad wiring 153. The bonding pad 157 may include, for example, gold (Au).

The first lower redistribution pattern 130 may include a first lower wiring 133 and a first seed pattern 135. The first seed pattern 135 and the first lower wiring 133 may be sequentially stacked on the upper surface of the lower insulating layer 110. That is, the first seed pattern 135 may cover the lower surface of the first lower wiring 133. The first seed pattern 135 may not extend onto a side surface of the first lower wiring 133. The first seed pattern 135 may include a material different from a material of the first lower wiring 133. For example, the first seed pattern 135 may include a conductive seed material. The conductive seed material may include copper, titanium, and/or alloys thereof. The first seed pattern 135 may function as a barrier layer to prevent diffusion of a material included in the first lower wiring 133.

The first lower redistribution pattern 130 may further include a first lower via (not shown). The first lower via may be positioned on the lower surface of the first lower wiring 133 and may be connected to the first lower wiring 133 without an interface. That is, a material forming the first lower via and the first lower wiring 133 may be formed as a unitary material by a single process step.

The second lower redistribution pattern 140 may include a second lower wiring 143, a second seed pattern 145, and an under bump via 147. The under bump via 147 of the second lower redistribution pattern 140 may penetrate a portion of the lowermost of the lower insulating layer 110, and thus the under bump via 147 may be provided in the lowermost of the lower insulating layer 110. The under bump via 147 of the second lower redistribution pattern 140 may be connected to the under bump pad 323. A width of the under bump via 147 of the second lower redistribution pattern 140 may decrease from the upper surface of the under bump via 147 to the lower surface of the under bump via 147. That is, the width of the under bump via 147 of the second lower redistribution pattern 140 may be relatively wide at the upper surface. In an embodiment, the width of the under bump via 147 of the second lower redistribution pattern 140 may be constant from the upper surface to the lower surface.

The second lower wiring 143 of the second lower redistribution pattern 140 may be provided on the upper surface of the under bump via 147 and may be connected to the under bump via 147 without an interface. That is, a material forming the second lower wiring 143 and the under bump via 147 may be formed as a unitary material by a single process step. A width of the second lower wiring 143 may be greater than the width of the upper surface of the under bump via 147. The second lower wiring 143 may extend onto the upper surface of the first lower insulating layer 110. In an embodiment, an interface may exist between the second lower wiring 143 and the under bump via 147. That is, the materials forming the second lower wiring 143 and the under bump via 147 may be formed separately, by different process steps.

The second seed pattern 145 of the second lower redistribution pattern 140 may be provided under the under bump via 147 and the second lower wiring 143 of the second lower redistribution pattern 140. In detail, the second seed pattern 145 may cover a lower surface and side surfaces of the under bump via 147 and a lower surface of the second lower wiring 143. The second seed pattern 145 may not extend onto the side surface of the second lower wiring 143. The second seed pattern 145 may be positioned between the under bump via 147 and the under bump pad 323. That is, the second seed pattern 145 may be in direct contact with the under bump pad 323. The second seed pattern 145 may include substantially the same material as the first seed pattern 135 and may perform the same function.

Referring to FIGS. 7A and 7B, the under bump via 147 may include first to fourth under bump vias 147a, 147b, 147c, and 147d. The first to fourth under bump vias 147a, 147b, 147c, and 147d may be disposed at regular intervals on the upper surface of the under bump pad 323.

In a plan view, the conductive structure 500, the lower redistribution pad via 151, and the first to fourth under bump vias 147a, 147b, 147c, and 147d may overlap the under bump pad 323. That is, the conductive structure 500, the lower redistribution pad via 151, and the first to fourth under bump vias 147a, 147b, 147c and 147d may be disposed on the under bump pad 323.

A diameter of each of the first to fourth under bump vias 147a, 147b, 147c, and 147d, a diameter of the conductive structure 500, and a diameter of the lower redistribution pad via 151 may be smaller than a diameter of the under bump pad 323. The diameter of each of the first to fourth under bump vias 147a, 147b, 147c, and 147d may be substantially the same as each other. The diameter of the conductive structure 500 may be greater than or substantially the same as the diameter of each of the first to fourth under bump vias 147a, 147b, 147c, and 147d. The diameter of the lower redistribution pad via 151 may be smaller than the diameter of each of the first to fourth under bump vias 147a, 147b, 147c, and 147d and the diameter of the conductive structure 500.

In a plan view, the conductive structure 500 may overlap the fourth under bump via 147d. The lower redistribution pad via 151 may be spaced apart from the conductive structure 500 and the first to fourth under bump vias 147a, 147b, 147c, and 147d. That is, the lower redistribution pad via 151 may not be vertically aligned with the conductive structure 500 and the first to fourth under bump vias 147a, 147b, 147c, and 147d.

The conductive structure 500, the lower redistribution pad via 151, and the first to fourth under bump vias 147a, 147b, 147c, and 147d may correspond to the core via 620 and the first lower via 131, and the first to fourth under bump vias 321a, 321b, 321c, and 321d of FIGS. 2A to 5B, respectively. That is, the conductive structure 500, the lower redistribution pad via 151, and the first to fourth under bump vias 147a, 147b, 147c, and 147d may be variously disposed as described with reference to FIGS. 3B, 4B and 5B.

Accordingly, in the semiconductor package 11, the conductive structure 500, the lower redistribution pad via 151, and one of the first to fourth under bump vias 147a, 147b, 147c, and 147d may have a structure in which they are not overlapped with each other, in a plan view. Therefore, cracks between the lower redistribution pad via 151 and the first lower wiring 133 may be prevented, thereby improving the reliability of the semiconductor package.

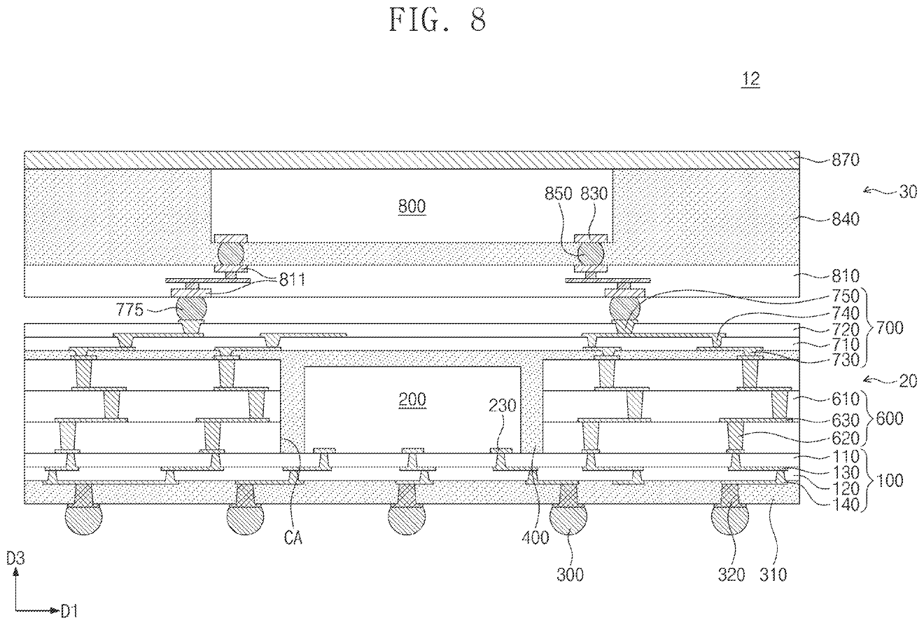

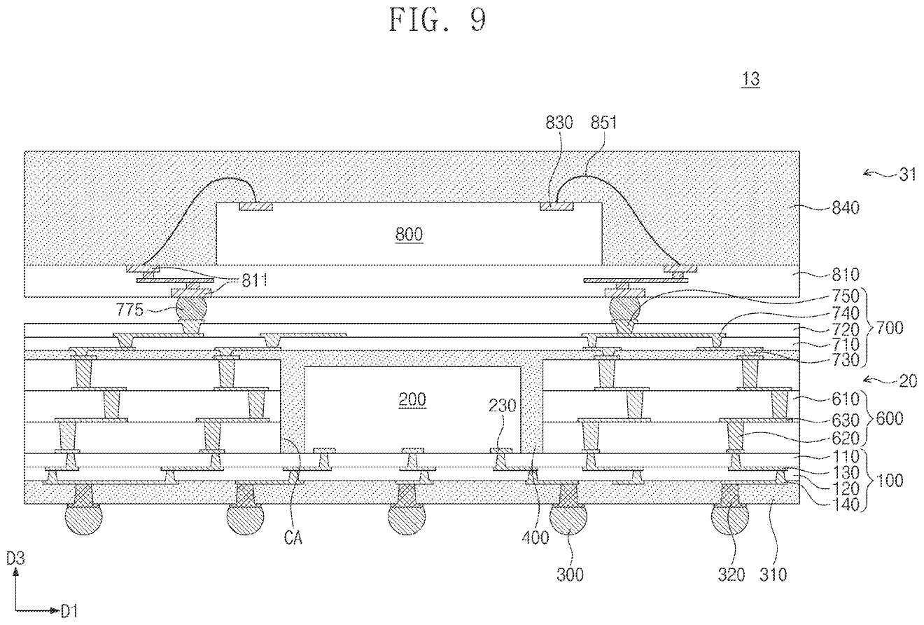

FIGS. 8 and 9 are cross-sectional views illustrating semiconductor packages according to embodiments of the inventive concept.

Hereinafter, for convenience of description, descriptions of the same items as those described with reference to FIG. 1 will be omitted and differences will be described in detail.

In an embodiment and referring to FIG. 8, a semiconductor package 12 may include a lower package 20, an upper package 30, and connection bumps 775. The lower package 20 may be substantially the same as the semiconductor package 10 described with reference to FIG. 1.

The upper package 30 may be disposed on the lower package 20. For example, the upper package 30 may be disposed on an upper redistribution layer 700. The upper package 30 may include an upper substrate 810, an upper semiconductor chip 800, and an upper molding layer 840.

The upper substrate 810 may be a printed circuit board or a redistribution layer. The substrate pads, including substrate pad 811, may be provided on upper and lower surfaces of the upper substrate 810.

The upper semiconductor chip 800 may be disposed on the upper substrate 810. The upper semiconductor chip 800 may include integrated circuits, which may include a memory circuit, a logic circuit, or a combination thereof. The upper semiconductor chip 800 may be a different type of semiconductor chip from the semiconductor chip 200 of the lower package 20. For example, the upper semiconductor chip 800 may be a memory chip.

Upper bumps, including upper bump 850, may be interposed between the upper substrate 810 and the upper semiconductor chip 800 to connect to the substrate pads and upper chip pads, including upper chip pad 830, of the upper semiconductor chip 800. The upper bumps, including upper bump 850, may include a solder material. Differently from that illustrated in FIG. 8, the upper bumps may be omitted, and the upper semiconductor chip 800 may be directly disposed on the upper substrate 810. That is, the upper chip pads, including upper chip pad 830, may be directly connected to the substrate pads 811. In this case, the upper chip pads and the substrate pads may form a hybrid bond. The hybrid bond herein refers to a bond in which two components including the same material are fused at their interface, and the interface may not be distinguished in a cross-sectional view.

The upper molding layer 840 may be provided on the upper substrate 810 to cover the upper semiconductor chip 800. The upper molding layer 840 may extend to a gap region between the upper substrate 810 and the upper semiconductor chip 800 to seal the upper bumps 850. In an embodiment, an underfill layer (not shown) may be further interposed in a gap region between the upper substrate 810 and the upper semiconductor chip 800. The upper molding layer 840 may include an insulating polymer such as an epoxy-based polymer.

The upper package 30 may further include an upper heat sink 870. The upper heat sink 870 may be disposed on an upper surface of the upper semiconductor chip 800 and an upper surface of the upper molding layer 840. The upper heat sink 870 may include at least one of a heat sink, a heat slug, and a heat transfer material layer. The upper heat sink 870 may include, for example, a metal. In an embodiment, the upper heat sink 870 may further extend on a side surface of the upper molding layer 840. In an embodiment, the upper heat sink 870 may be omitted, and the upper molding layer 840 may further cover an upper surface of the upper semiconductor chip 800.

The connection bumps, including connection bump 775, may be interposed between the upper redistribution layer 700 and the upper substrate 810 to connect to the redistribution pads 750 and the substrate pads, including substrate pad 811, of the upper substrate 810. Accordingly, the upper package 30 may be electrically connected to the lower package 20 through the connection bumps, including connection bump 775. The connection bumps may include solder materials. The connection bumps may further include metal pillars. Electrical connection with the upper package 30 may mean electrical connection with integrated circuits in the upper semiconductor chip 800.

In an embodiment, the upper substrate 810 and the connection bumps may be omitted, and the upper bumps, including upper bump 850, may be directly connected to the redistribution pads, such as redistribution pad 750. In this case, the upper molding layer 840 may be in direct contact with an upper surface of the upper redistribution layer 700. In an embodiment, the upper substrate 810, the connection bumps, and the upper bumps may be omitted, and the upper chip pads, including upper chip pad 830, of the upper semiconductor chip 800 may be directly connected to the redistribution pads, including redistribution pad 750. In this case, the upper chip pads and the redistribution pads may form a hybrid bond.

Referring to FIG. 9, a semiconductor package 13 may include a lower package 20, an upper package 31, and the connection bumps, including connection bump 775. The lower package 20 may be substantially the same as the semiconductor package 10 described with reference to FIG. 1. The connection bumps may be substantially the same as those described with reference to FIG. 8.

The upper package 31 may be disposed on the lower package 20. The upper package 31 may include an upper substrate 810, an upper semiconductor chip 800, and an upper molding layer 840. The upper substrate 810 and the upper molding layer 840 may be substantially the same as those described with reference to FIG. 8.

In an embodiment, upper chip pads, including upper chip pad 830, of the upper semiconductor chip 800 may be provided on an upper surface of the upper semiconductor chip 800. Bonding wires, including bonding wire 851, may be provided on the upper chip pads, including upper chip pad 830, to be electrically connected to the upper chip pads and substrate pads, including substrate pad 811.

Referring back to FIGS. 8 and 9, the upper packages 30 and 31 may be provided on the lower package 20, and thus an external force may be applied to the lower package 20 in the third direction D3. The lower package 20 may have a structure that avoids the core via 620, the first lower via 131, and one of the first to fourth under bump vias 321a, 321b, 321c, and 321d as described with reference to FIGS. 2A to 5B being vertically aligned. Accordingly, the cracks between the core pad 630 and the first lower via 131 may be prevented, thereby improving the reliability of the semiconductor package.

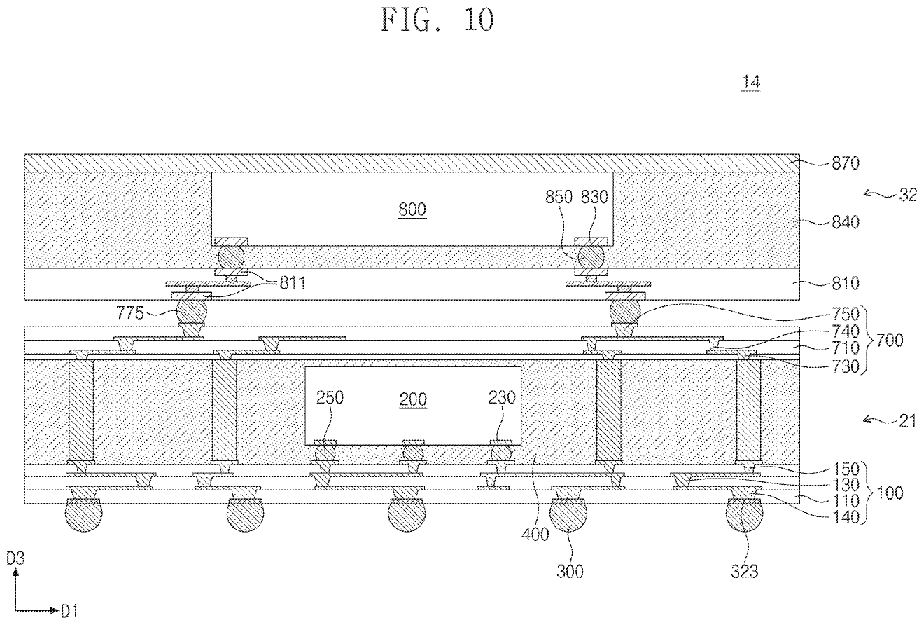

FIG. 10 is a cross-sectional view illustrating a semiconductor package according to embodiments of the inventive concept.

Hereinafter, for convenience of description, descriptions of the same items as those described with reference to FIGS. 6 and 8 may be omitted and differences will be described in detail.

In an embodiment and referring to FIG. 10, a semiconductor package 14 may include a lower package 21, an upper package 32, and the connection bumps, including connection bump 775. The lower package 21 may be substantially the same as the semiconductor package 11 described with reference to FIG. 6. The connection bumps, including connection bump 775, may be substantially the same as those described with reference to FIG. 8.

The upper package 32 may be substantially the same as the upper package 30 described with reference to FIG. 8. In an embodiment, the upper chip pads, including upper chip pad 830, of the upper semiconductor chip 800 may be provided on the upper surface of the upper semiconductor chip 800 and may be connected to the substrate pads, including substrate pad 811, through bonding wires. That is, the upper package 32 may be substantially the same as the upper package 31 described with reference to FIG. 9.

As the upper package 32 is provided on the lower package 21, an external force may be applied to the lower package 21 in the third direction D3. As described with reference to FIGS. 7A and 7B, the lower package 21 may have a structure that avoids the lower redistribution pad via 151, the conductive structure 500, and one of the first to fourth under bump vias 147a, 147b, 147c and 147d being vertically aligned. Accordingly, the external force concentrated on the lower redistribution pad via 151 may be dispersed, and cracks in the lower redistribution pad via 151 may be prevented, thereby improving the reliability of the semiconductor package.

The semiconductor package according to an embodiment of the inventive concept may include the core via passing through the core layer, the first lower via positioned below the core via, and the under bump via. In a plan view, at least one of the core via, the first lower via, and the under bump via may be spaced apart from each other. Accordingly, even when the upper package is positioned on the semiconductor package, the compressive stress applied to the first lower via may be reduced. Accordingly, it is possible to prevent the crack from occurring between the first lower via and the core via, thereby improving the reliability and durability of the semiconductor package.

While embodiments are described above, a person skilled in the art may understand that many modifications and variations are made without departing from the spirit and scope of the inventive concept defined in the following claims. Accordingly, example embodiments of the inventive concept should be considered in all respects as illustrative and not restrictive, with the spirit and scope of the inventive concept being indicated by the appended claims.

1. A semiconductor package comprising:
a lower redistribution layer including a lower wiring and a lower via;
a core layer on the lower redistribution layer and including a core via; and
an under bump structure including an under bump pad on a lower surface of the lower redistribution layer and an under bump via connecting the lower wiring and the under bump pad,
wherein the under bump pad overlaps the under bump via, the lower via, and the core via in a plan view, and
wherein the under bump via is spaced apart from at least one of the lower via and the core via in the plan view.

2. The semiconductor package of claim 1, further comprising:
a semiconductor chip on the lower redistribution layer; and
a molding layer on the lower redistribution layer between the core layer and the semiconductor chip.

3. The semiconductor package of claim 1, further comprising:
a passivation layer between the lower redistribution layer and the under bump structure; and
an external terminal connected to the under bump pad.

4. The semiconductor package of claim 1, wherein a width of the lower via of the lower redistribution layer is narrower from a lower surface to an upper surface of the lower via.

5. The semiconductor package of claim 1, wherein the under bump via overlaps the core via, in the plan view.

6. The semiconductor package of claim 1, wherein the under bump via is provided in plurality, and
wherein the plurality of under bump vias are disposed on the under bump pad at regular intervals.

7. The semiconductor package of claim 6, wherein the plurality of under bump vias and the core via are disposed on the under bump pad and spaced apart from each other at regular intervals.

8. The semiconductor package of claim 6, wherein the lower via and the core via are disposed between the plurality of under bump vias and overlap each other, in the plan view.

9. The semiconductor package of claim 6, wherein the lower via, the core via, and the plurality of under bump vias are spaced apart from each other, in the plan view.

10. The semiconductor package of claim 1, wherein a diameter of the lower via is smaller than a diameter of the core via, and the diameter of the lower via is smaller than a diameter of the under bump via.

11. The semiconductor package of claim 1, wherein a combined height of the core via, the lower via, and the under bump via is at least 100 μm.

12. A semiconductor package comprising:
a semiconductor chip;
a lower redistribution layer including a lower via and a lower wiring on a lower surface of the semiconductor chip;
an upper redistribution layer on an upper surface of the semiconductor chip;
a connection structure connecting between the lower redistribution layer and the upper redistribution layer and located on a side of the semiconductor chip;
an under bump pad on a lower surface of the lower redistribution layer; and
an under bump via between the lower wiring and the under bump pad,
wherein the lower via, the connection structure, and the under bump via overlap the under bump pad, in a plan view, and
wherein the lower via is spaced apart from the under bump via, in the plan view.

13. The semiconductor package of claim 12, wherein the semiconductor chip is disposed on a center region of the lower redistribution layer, on a plane view.

14. The semiconductor package of claim 12, wherein the semiconductor chip includes a chip pad, and the chip pad of the semiconductor chip is in direct contact with the lower redistribution layer.

15. The semiconductor package of claim 12, further comprising bumps between the semiconductor chip and the lower redistribution layer.

16. The semiconductor package of claim 12, wherein the connection structure includes a core insulating pattern and a core via, and
wherein the core insulating pattern and the core via are spaced apart from the semiconductor chip, in the plan view.

17. The semiconductor package of claim 12, wherein the connection structure includes a molding layer and a conductive structure penetrating the molding layer, and
wherein the molding layer is in contact with the semiconductor chip.

18. The semiconductor package of claim 12, wherein the upper redistribution layer includes an upper via and an upper wiring, and
wherein the upper via has a width that is narrower from an upper surface to a lower surface of the upper via.

19. A semiconductor package comprising:
a lower package; and
an upper package disposed on the lower package and including an upper semiconductor chip,
wherein the lower package includes:
a lower redistribution layer including a lower insulating layer, a seed pattern, a lower via, and a lower wiring;
a lower semiconductor chip on the lower redistribution layer;
a core layer surrounding the lower semiconductor chip on the lower redistribution layer and including a core insulating pattern, a core via, and a core pad;
an under bump structure provided on a lower surface of the lower redistribution layer and including an under bump pad and a plurality of under bump vias;
an external terminal connected on a lower surface of the under bump pad;
a molding layer covering the lower semiconductor chip and the core layer on the lower redistribution layer; and
an upper redistribution layer connected to the lower redistribution layer through the core layer on the molding layer,
wherein the lower via, the core via, and the plurality of under bump vias are disposed on the under bump pad, and
wherein the lower via, the core via, and the plurality of under bump vias are not vertically aligned with each other.

20. The semiconductor package of claim 19, wherein a diameter of the under bump pad is greater than diameters of the lower via, the core via, and the plurality of under bump vias.
